(19) United States
(12) Patent Application Publication
(10) Pub. No.: US 2026/0362641 A1
(43) Pub. Date: Nov. 12, 2026

(54) LIQUID COOLING SYSTEM AND METHOD FOR USE IN BURN-IN TESTING

(71) Applicant: Expert International Mercantile Corporation, Hsinchu (TW)

(72) Inventors: WEI-CHIH SUN, Hsinchu (TW); WEN-HSU CHANG, Hsinchu (TW); CHIA-CHUN HO, Hsinchu (TW); YI-HAO HONG, Hsinchu (TW); CHING-FENG TENG, Hsinchu (TW); YU-RUO YING, Hsinchu (TW); KUAN-TING LIN, Hsinchu (TW)

(21) Appl. No.: 19/293,011

(22) Filed: Aug. 7, 2025

(30) Foreign Application Priority Data
May 6, 2025 (TW) 114116986

(51) Int. Cl. H05K 7/20; G01R 31/28

(52) U.S. Cl. CPC H05K 7/20263; G01R 31/2863; H05K 7/20272; H05K 7/20763

(57) ABSTRACT

A liquid cooling system for use in burn-in testing includes: a rack having a liquid-cooling heat dissipation module; and a liquid-cooling burn-in board including a plurality of burn-in sockets each fluidly connected to a different one of the burn-in sockets via a fluid pipeline. When the liquid-cooling burn-in board is inserted into the rack, a fluid pipeline of the liquid-cooling burn-in board is fluidly connected to the liquid-cooling heat dissipation module to form a closed loop, allowing a coolant within the closed loop to undergo heat exchange in the liquid-cooling heat dissipation module to ensure the stability and reproducibility of high-power devices under test during burn-in testing.

### CROSS-REFERENCE TO RELATED APPLICATIONS

This non-provisional application claims priority to and the benefit of Taiwan Application Serial Number 114116986, filed on May 6, 2025, which is incorporated by reference herein in its entirety.

### BACKGROUND OF THE INVENTION

### Field of the Invention

The present disclosure relates to a liquid cooling system and method for use in burn-in testing, and more particularly to a novel burn-in testing cooling system and cooling method.

### Description of the Prior Art

Burn-in testing performed on devices under test entails performing a stress test on the devices under test under high-temperature and high-voltage conditions to simulate long-duration operating environments and screen for potentially defective chips. The industry sector typically adopts air-cooling heat dissipation technology, using fans to cool devices under test through forced air convection, in order to maintain temperature stability during testing. However, as devices under test consume increasing amounts of power, air-cooling systems are increasingly unable to dissipate heat effectively to meet testing requirements of high-power devices under test, leading to difficulty in controlling temperature during testing and affecting the accuracy and reliability of the test results.

To address the above issues, some of conventional air-cooling systems have been improved, for example, by Increasing fan speeds or using liquid metal for thermal conduction. However, the prior art is still confronted with issues, such as limited heat dissipation efficiency, poor temperature uniformity, and excessive power consumption. Therefore, the industry sector urgently needs a more efficient temperature control method to ensure the stability and reproducibility of high-power devices under test during burn-in testing.

### SUMMARY OF THE INVENTION

The disclosure, addressing the aforesaid technical bottleneck, provides a device under test burn-in testing solution based on the principles of water-cooling heat dissipation to precisely control the temperature of the device under test and enhance test reliability and heat dissipation efficiency by liquid-cooling technology.

To achieve the above and other objectives, the disclosure provides a liquid cooling system for use in burn-in testing, comprising: a rack having a liquid-cooling heat dissipation module; and a liquid-cooling burn-in board comprising a plurality of burn-in sockets, wherein each of the burn-in socket being fluidly connected to the another burn-in sockets via a fluid pipeline, wherein, when the liquid-cooling burn-in board is inserted into the rack, a fluid pipeline of the liquid-cooling burn-in board is fluidly connected to the liquid-cooling heat dissipation module to form a closed loop, allowing a coolant within the closed loop to undergo heat exchange in the liquid-cooling heat dissipation module.

In an embodiment, the liquid-cooling heat dissipation module has a water tank, a transport conduit and a plurality of fans, with the water tank configured to contain the coolant and fluidly connected to the fluid pipeline of the liquid-cooling burn-in board via the transport conduit, and the plurality of fans disposed on the water tank to dissipate heat from the coolant in the water tank.

In an embodiment, the liquid-cooling burn-in board is fluidly connected to a fluid pipeline of the liquid-cooling heat dissipation module via a pair of fluid connectors.

In an embodiment, bottoms of the plurality of burn-in sockets of the liquid-cooling burn-in board are further fluidly connected to a second fluid pipeline, and the second fluid pipeline is fluidly connected to a fluid pipeline of the liquid-cooling heat dissipation module via a pair of second fluid connectors.

In an embodiment, the pair of fluid connectors is a blind mate connector.

In an embodiment, the liquid-cooling heat dissipation module is also configured to further introduce the coolant into the closed loop when the fluid pipeline of the liquid-cooling burn-in board is fluidly connected to the liquid-cooling heat dissipation module.

In an embodiment, the liquid cooling system further comprises a vacuum module comprising: a pressure sensing unit for monitoring a pressure level within the closed loop; a vacuum pump for regulating a pressure within the closed loop by activating or deactivating based on whether the pressure level falls within a predetermined range.

In an embodiment, the liquid cooling system further comprises a vacuum module comprising: a water level sensor for monitoring a leakage level within the closed loop; a water pump for introducing the coolant from the closed loop to the liquid-cooling heat dissipation module according to the leakage level.

In an embodiment, the rack further comprises a guide rail configured to guide the liquid-cooling burn-in board into connection with the liquid-cooling heat dissipation module, wherein the guide rail having a pin, and the liquid-cooling burn-in board having a positioning mechanism, when the liquid-cooling burn-in board is connected to the liquid-cooling heat dissipation module, the liquid-cooling burn-in board engages with the pin via the positioning mechanism to allow the liquid-cooling burn-in board to be positioned at a location forming the closed loop.

In an embodiment, the positioning mechanism has a first portion, a second portion, and an arm portion connected to the first portion and the second portion, the first portion being a concave portion, when the liquid-cooling burn-in board moves along the guide rail, the first portion engages with the pin to drive rotation of the arm portion to cause the second portion to latch into a containment space in the liquid-cooling burn-in board, so as to allow the liquid-cooling burn-in board to be positioned at a location forming the closed loop.

In an embodiment, the liquid-cooling burn-in board receives power from the rack via a busbar connector.

In an embodiment, the liquid-cooling heat dissipation module is a rear door heat exchanger (RDHx).

In an embodiment, a check directional valve is disposed at at least one of an inlet and outlet of a fluid pipeline corresponding in position to each of the burn-in sockets.

In an embodiment, the rack comprises a back door and a liquid cooling module, with the liquid cooling module positioned proximate to the back door to allow the liquid cooling module to absorb heat released by the liquid-cooling heat dissipation module.

In an embodiment, the rack comprises a back door having a plurality of fans.

To achieve the above and other objectives, the disclosure provides a liquid-cooling method for use in burn-in testing, comprising the steps of: providing a liquid-cooling burn-in board comprising a plurality of burn-in sockets, wherein each of the burn-in sockets being fluidly connected to the another burn-in socket via a fluid pipeline; providing a liquid-cooling heat dissipation module disposed in a rack and comprising a water tank and a transport conduit; and fluidly connecting a fluid pipeline of the liquid-cooling burn-in board to the transport conduit of the liquid-cooling heat dissipation module to form a closed loop, so as to allow a coolant in the closed loop to undergo heat dissipation via the liquid-cooling heat dissipation module.

In an embodiment, the liquid-cooling method further comprises the steps of: monitoring a pressure level within the closed loop; and regulating a pressure within the closed loop based on whether a pressure level falls within a predetermined range.

In an embodiment, the liquid-cooling method further comprises the steps of: monitoring a leakage level within the closed loop; and delivering the coolant from the closed loop to the liquid-cooling heat dissipation module according to the leakage level.

In an embodiment, a negative pressure is generated in the liquid-cooling heat dissipation module using a gas pump connected to the closed loop, so as to extract the coolant from the closed loop to the liquid-cooling heat dissipation module.

In an embodiment, the negative pressure indicates that pressure within the closed loop is lower than external ambient pressure when the liquid-cooling heat dissipation module is configured to contain the coolant.

In an embodiment, the coolant is introduced into the closed loop upon confirmation of the state of the burn-in board.

### BRIEF DESCRIPTION OF THE DRAWINGS

FIG. 1A is a perspective view of a system of the disclosure.

FIG. 1B is a perspective view showing the system from another angle according to the disclosure.

FIG. 1C is a front view of the system of the disclosure.

FIG. 1D is a side view of the system of the disclosure.

FIG. 1E is a rear view of the system of the disclosure.

FIG. 2A is a perspective view of the system from another angle according to the disclosure, showing both a front door and a back door in an open state while omitting a side door.

FIG. 2B is a front view of the system of the disclosure, showing both the front door and the back door in an open state.

FIG. 2C is a side view of the system of the disclosure, showing both the front door and the back door in an open state.

FIG. 2D is a rear view of the system of the disclosure, showing both the front door and the back door in an open state.

FIG. 3 is a block diagram of the electronic components of the disclosure.

FIG. 4A is a top view of a burn-in board, back board, and liquid-cooling heat dissipation module of the disclosure.

FIG. 4B is a perspective view of the burn-in board, back board, and liquid-cooling heat dissipation module of the disclosure.

FIG. 4C is a perspective view of a plurality of burn-in boards, the back boards, and the liquid-cooling heat dissipation modules joined together according to the disclosure.

FIG. 4D is a schematic view of a fluid connector fluidly connected to a connection interface according to the disclosure.

FIG. 4E is a schematic view of a busbar connector electrically connected to the back board of the disclosure.

FIG. 5 is a top view of a coolant flow path of the disclosure.

FIG. 6A is a schematic view of a check valve assembly according to the first embodiment of the disclosure.

FIG. 6B is a schematic view of the check valve assembly operatively positioned in an open state according to the first embodiment of the disclosure.

FIG. 6C is a schematic view of the check valve assembly operatively positioned in a closed state according to the first embodiment of the disclosure.

FIG. 7A is a schematic view of a check valve assembly operatively positioned in an open state according to the second embodiment of the disclosure.

FIG. 7B is a schematic view of the check valve assembly operatively positioned in a closed state according to the second embodiment of the disclosure.

FIG. 8 is a schematic view of a bottom side of the burn-in board according to the disclosure.

FIG. 9A is a schematic view of a device under test disposed in a burn-in socket according to the disclosure.

FIG. 9B is a schematic view of the burn-in board disposed in a rack according to the disclosure.

FIG. 10 is a top view of the burn-in board of the disclosure, further showing a positioning mechanism.

FIG. 11 is a schematic view of the positioning mechanism of the disclosure.

FIG. 12A through FIG. 12C are schematic views of the positioning mechanism, showing its unlocked position through its locked position according to the disclosure.

FIG. 13A and FIG. 13B are schematic views of the positioning mechanism disposed in a containment space according to the disclosure.

FIG. 14 is a flowchart of a liquid-cooling method of the disclosure.

FIG. 15 is a perspective view of a system having a liquid cooling module according to the disclosure.

FIG. 16A is a perspective view of the back door according to the first embodiment of the disclosure.

FIG. 16B is a perspective view of the back door, showing the back door in an open state while omitting the liquid cooling module according to the first embodiment of the disclosure.

FIG. 17A is a perspective view of the back door according to the second embodiment of the disclosure.

FIG. 17B is a perspective view of the back door, showing the back door in an open state while omitting the liquid cooling module according to the second embodiment of the disclosure.

### DETAILED DESCRIPTION OF THE EMBODIMENTS

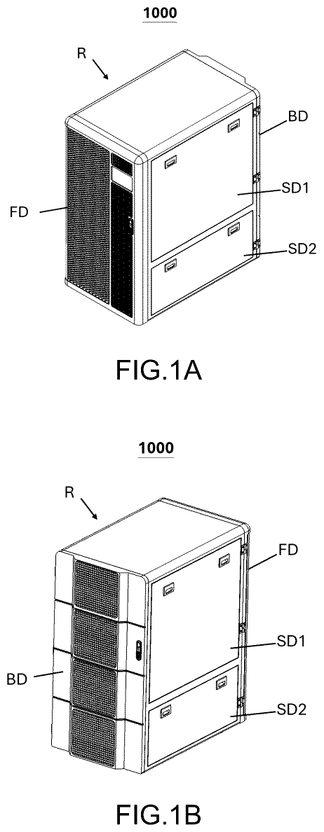

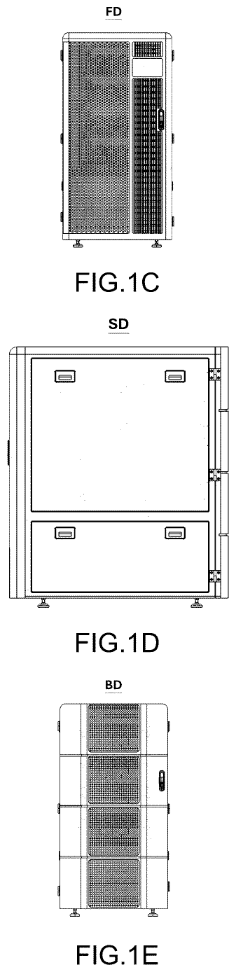

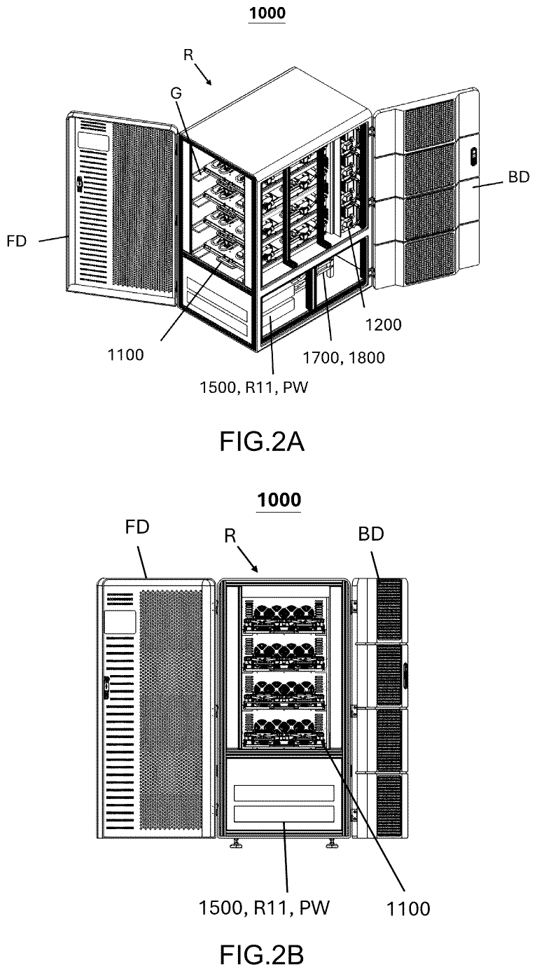

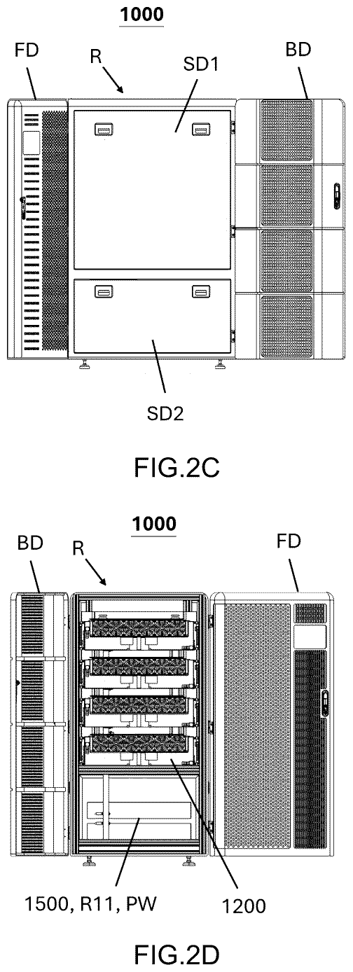

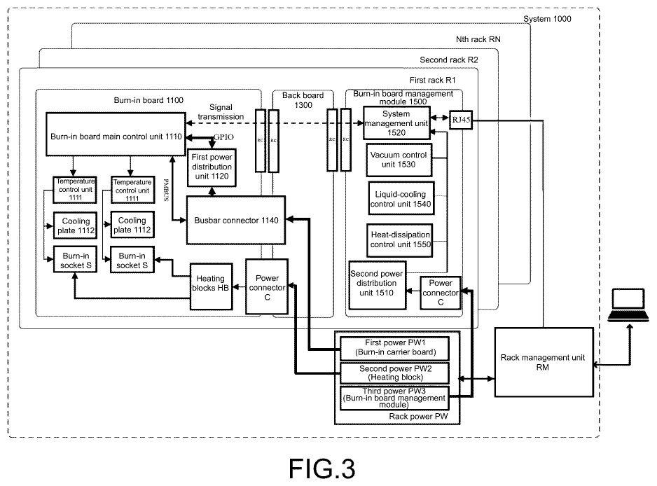

Referring to FIG. 1A~1E and FIG. 2A~2D, a system 1000 of the disclosure comprises at least one rack R. The rack R comprises a front door FD, upper side door SD1, lower side door SD2 and back door BD. The front door FD, upper side door SD1, lower side door SD and back door BD of the rack R and the top side and bottom side of the rack R jointly form a receiving space. A first space is jointly defined by the upper side door SD1, front door FD and back door BD. a plurality of pairs of guide rails G are disposed in the first space. a plurality of liquid-cooling heat dissipation modules 1200 are disposed in the first space and positioned proximate to the back door BD. Each pair of guide rails G corresponds to a corresponding one of the liquid-cooling heat dissipation modules 1200; thus, each burn-in board 1100 can be guided into the first space via a pair of guide rails G to join a corresponding one of the liquid-cooling heat dissipation modules 1200, thereby creating a fluidic connection. According to the disclosure, the first space receives different types of burn-in boards 1100, depending on design and need. According to the disclosure, the lower side door SD2, front door FD and back door BD jointly define a second space. A rack management unit RM, rack power PW, and burn-in board management module 1500 are disposed in the second space. Furthermore, a vacuum module 1700 and a liquid cooling module 1800, both fluidly connected to the liquid-cooling heat dissipation modules 1200, are disposed in the second space. In an embodiment of the disclosure, the front door FD, upper side door SD1, lower side door SD2 and back door BD can be opened and closed independently of the others to not only allow operation personnel to monitor a burn-in process but also enable operation personnel to repair or replace components in the rack R. The front door FD and the upper side door SD1 are configured similarly to the back door BD, composed of a plurality of panels, including a mesh panel to facilitate the entry of cool air into the rack, improving heat dissipation and preventing internal components from overheating, or a dust filter to prevent dust from intruding into the rack, reducing the accumulation of dust on components and the resultant deterioration in heat dissipation efficiency.

Referring to FIG. 3, there is a block diagram showing the connections between the components of the system 1000. The connections between the components will be briefly described below. The system 1000 of the disclosure comprises a first rack R1, second rack R2 through N^{th} rack RN. The racks each comprise therein a plurality of modules and units. Take the first rack R1 as an example, the first rack R1 comprises a rack management unit RM, rack power PW, burn-in board management module 1500, and the burn-in board 1100 connected to the liquid-cooling heat dissipation modules 1200 via the guide rails G. The burn-in board 1100 is further connected to the liquid-cooling heat dissipation modules 1200 via a back board 1300 (as described later). The liquid-cooling heat dissipation modules 1200, vacuum module 1700 and liquid cooling module 1800 are electrically connected to the burn-in board management module 1500 and controlled by the burn-in board management module 1500. According to the disclosure, the burn-in board 1100, the back board 1300, and the burn-in board management module 1500 are both configured a signal connector RC such that the burn-in board management module 1500 can receive a feedback signal from the burn-in board 1100 or send a control signal to the burn-in board 1100 via the signal connector RC. In a specific embodiment of the disclosure, either one burn-in board 1100 is electrically connected to one burn-in board management module 1500 via one back board 1300, or the plurality of burn-in boards 1100 are electrically connected to one burn-in board management module 1500 via the plurality of back boards 1300 respectively.

The power transmission of components of the disclosure is described below. According to the disclosure, all the components in the rack have to be supplied with power in order to operate, and the rack power PW comprises a first power PW1 configured to supply electric power to the burn-in board 1100, a second power PW2 configured to supply electric power to a heating block HB, and a third power PW3 configured to supply electric power to the burn-in board management module 1500. The first power PW1 is supplied to the back board 1300 and further electrically connected to the back board 1300 via a busbar connector 1140 of the burn-in board 1100 and finally supplied to the burn-in board 1100. Furthermore, the first power PW1 is supplied to a first power distribution unit 1120 and distributed by the first power distribution unit 1120 to the other components, such as a burn-in board main control unit 1110, temperature control unit 1111, cooling plate 1112 or burn-in socket S. According to the disclosure, the heating block HB is disposed in the burn-in socket S to enable the heating of a device under test. The electric power supplied by the second power PW2 to the heating block HB is greater than the electric power from the first power PW1. For instance, each heating block HB requires an electric power of 300V, whereas 48V should suffice for the electric power supplied by the first power PW1; thus, the electric power from the second power PW2 is transmitted to the heating block HB via a power connector C of the back board 1300 and the burn-in board 1100. According to the disclosure, the third power PW3 supplies electric power to the burn-in board management module 1500 via the power connector C of the burn-in board management module 1500. The electric power from the third power PW3 is supplied to a second power distribution unit 1510 and further distributed by the second power distribution unit 1510 to a system management unit 1520, vacuum control unit 1530, and liquid-cooling control unit 1540. According to the disclosure, the rack management unit RM monitors and controls the usage of the electric power from the first power PW1, the second power PW2, and the third power PW3. Furthermore, the rack management unit RM monitors, via the first power distribution unit 1120 and the second power distribution unit 1510, the electric power for use by the components. Furthermore, the rack management unit RM receives or transmits signals via a network port, such as RJ45.

The functions of the electronic components illustrated by FIG. 3 are described below. According to the disclosure, the rack management unit RM functions as a core management system of the entire rack and is essentially configured to monitor the operating state of the burn-in board 1100 and the burn-in board management module 1500 and provide the required electric power and control commands as needed. The burn-in board 1100 tests the reliability and durability of electronic components or a device under test and essentially comprises a burn-in board main control unit 1110, temperature control unit 1111, cooling plate 1112, first power distribution unit 1120, busbar connector 1140, burn-in socket S, and heating block HB disposed in the burn-in socket S. The burn-in board main control unit 1110 functions as a core control module of the burn-in board 1100, controls the overall operation of the burn-in board 1100, communicates with an external apparatus (for example, exchanges signals with a test apparatus) via GPIO, and communicates with the temperature control unit 1111 and the first power distribution unit 1120 via PMBUS. The temperature control unit 1111 is configured to monitor and regulate the temperature of testing components and connected to the cooling plate 1112. The cooling plate 1112 is configured for reducing the temperature and precludes overheating during a testing process. The first power distribution unit 1120 is configured to distribute the electric power from the rack power PW to the components in the burn-in board 1100. The busbar connector 1140 is configured to be electrically connected to the first power distribution unit 1120 to transmit electric power from the third power PW3 to the first power distribution unit 1120. The burn-in socket S is disposed on the burn-in board 1100 to insert a device under test, allowing burn-in testing to be performed on the device under test. The heating block HB is disposed in the burn-in socket S to directly contact with the device under test for heating a test sample to a specific temperature through resistor heating or with a thermal conduction component, so as to simulate prolonged heat-generating conditions, thereby assessing whether the device under test exhibits aging, performance decline, or failure when subjected to sustained high temperatures.

According to the disclosure, the burn-in board management module 1500 comprises the second power distribution unit 1510, the system management unit 1520, the vacuum control unit 1530, the liquid-cooling control unit 1540, and a heat-dissipation control unit 1550. The vacuum control unit 1530 is electrically connected to the vacuum module 1700 to control the operation of the vacuum module 1700. The liquid-cooling control unit 1540 is electrically connected to the liquid cooling module 1800 to control the operation of the liquid cooling module 1800. According to the disclosure, the second power distribution unit 1510 is configured to distribute the electric power from the third power PW3 to different units in the burn-in board management module 1500. According to the disclosure, the system management unit 1520 functions as the core of the burn-in board management module 1500, monitors the burn-in process, and handles various abnormal events (for example, leakage or abnormality of pressure, voltage, current or temperature). In a specific embodiment of the disclosure, the system management unit 1520 communicates with an external apparatus, such as a server or monitoring computer, via an RJ45 interface. According to the disclosure, the vacuum control unit 1530 is opened or closed, depending on whether the pressure level within a coolant pipeline (that is, a closed loop) falls within a predetermined range, so as to control the vacuum module 1700 generating a vacuum inside the coolant pipeline and thereby regulate the pressure within the coolant pipeline. According to the disclosure, the liquid-cooling control unit 1540 is configured to introduce a coolant into the closed loop as soon as fluid pipelines T100 of the burn-in boards 1100 are fluidly connected to the liquid-cooling heat dissipation modules 1200. According to the disclosure, the heat-dissipation control unit 1550 comprises a testing component, such as a resistance temperature detector, and a flow meter. The heat-dissipation control unit 1550 is configured to regulate the heat dissipation level of the liquid-cooling heat dissipation modules 1200, for example, through adjusting the flow rate of the coolant or adjusting the rotation speed of the fans, according to temperature data obtained by the testing component.

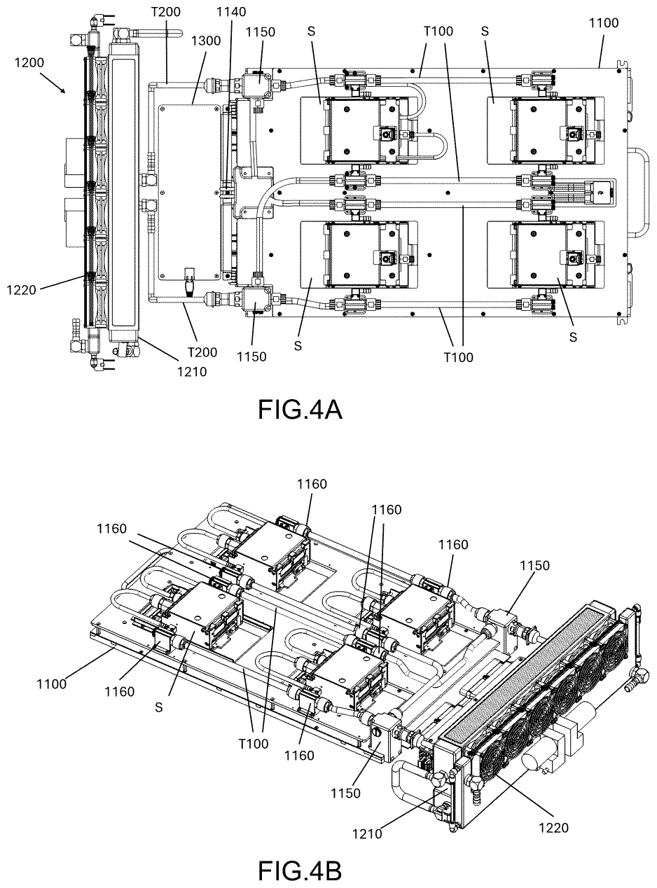

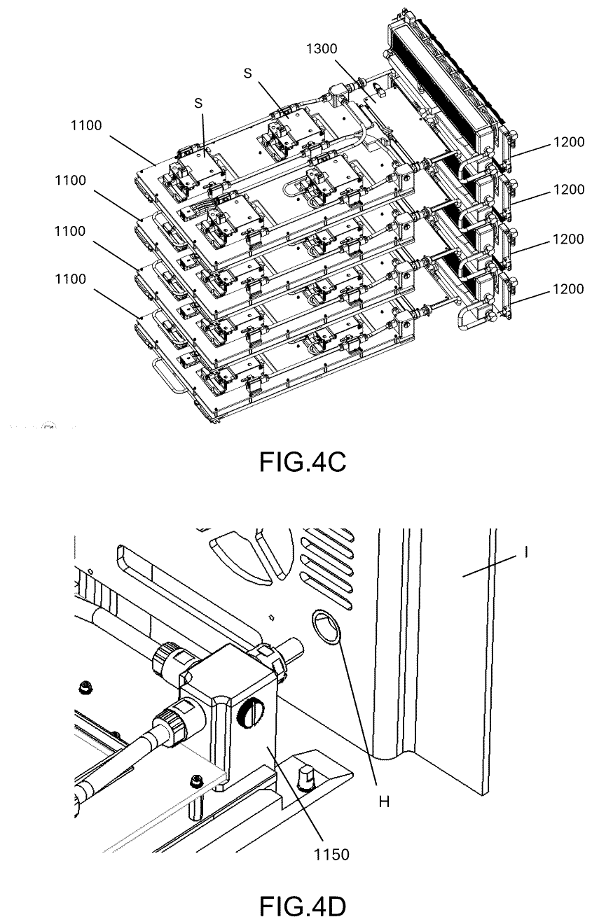

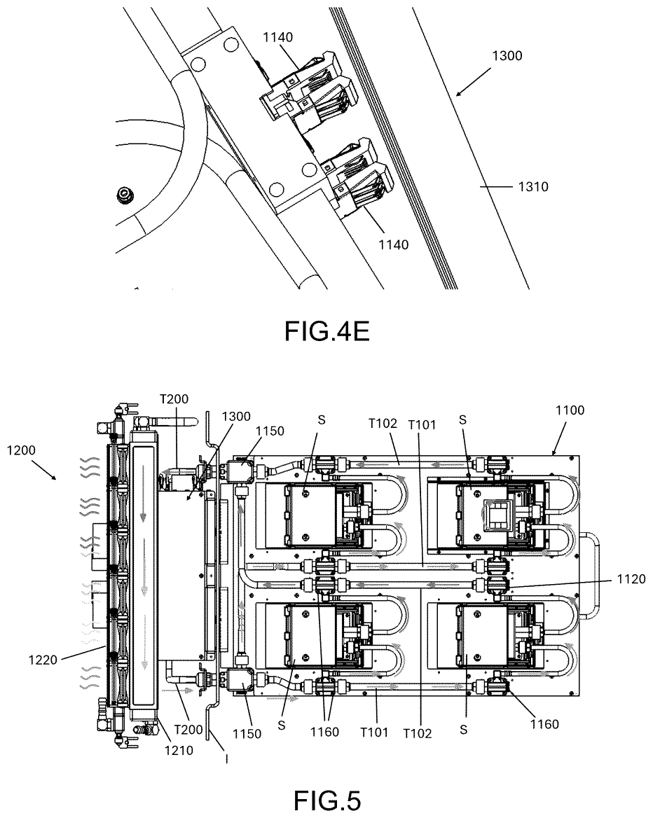

The components for use in heat dissipation according to the disclosure are described below. As shown in FIG. 4A~4C and FIG. 5, according to the disclosure, the burn-in board 1100 is a liquid-cooling burn-in board made of PCB and has a top side and a bottom side. A plurality of burn-in sockets S are disposed on the top side of the burn-in board 1100 and arranged in an array. The burn-in sockets S are fluidly connected via the fluid pipelines T100. As shown in FIG. 5, the fluid pipelines T100 each comprise an input closed loop T101 and an output closed loop T102. The input closed loop T101 is a fluid path of the coolant that has not yet undergone heat absorption or has undergone heat dissipation. The output closed loop T102 is a fluid path of the coolant that corresponds in position to the burn-in sockets S and removes heat from the device under test. In other words, the coolant that has undergone heat dissipation within the input closed loop T101 is inputted into the burn-in sockets S, and the output closed loop T102 outputs high-temperature coolant from the burn-in sockets S. According to the disclosure, the input closed loop T101 is configured to eventually converge at a fluid connector 1150 disposed on the burn-in board 1100 and positioned proximate to the burn-in board management module 1500, and the output closed loop T102 is configured to converge at another fluid connector 1150. In a specific embodiment of the disclosure, the input closed loop T101, the output closed loop T102, and the fluid connector 1150 are symmetrically disposed on the burn-in board 1100, the fluid connector 1150 is provided in the form of one pair of blind mate connectors, for example, UQD04 liquid-cooling universal quick connectors, but the disclosure is not limited thereto.

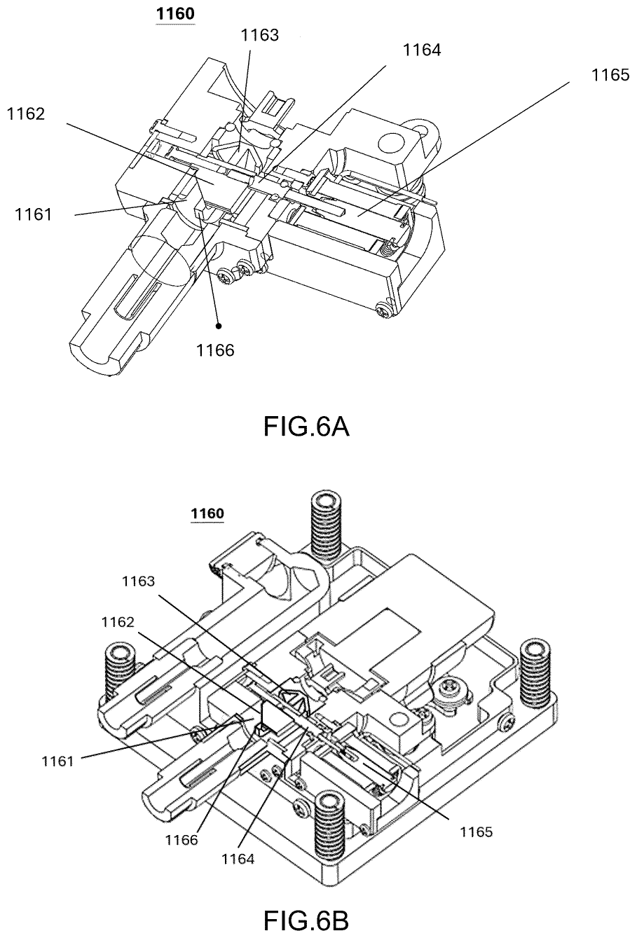

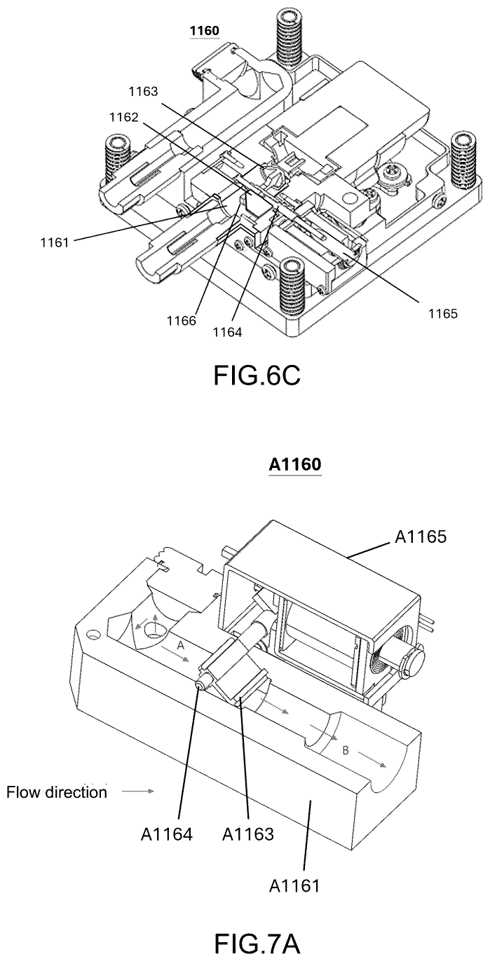

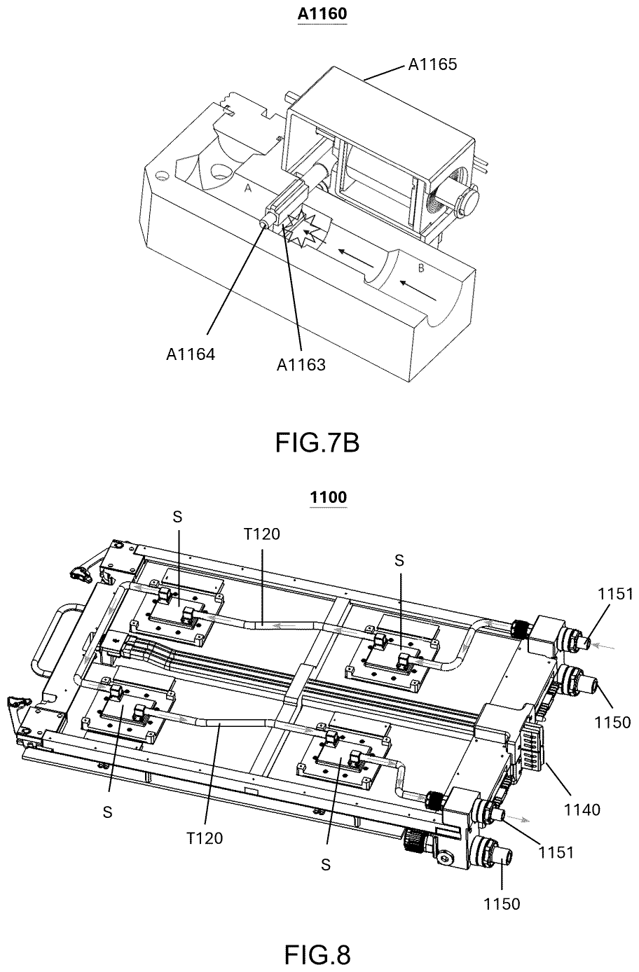

According to the disclosure, a check valve assembly 1160 is disposed at the junction of the input closed loop T101 and the outlet of a fluid pipeline of each burn-in socket S, at the junction of the input closed loop T101 and the inlet of the fluid pipeline of the burn-in socket S, at the junction of the output closed loop T102 and the outlet of the fluid pipeline of each burn-in socket S, and at the junction of the output closed loop T102 and the inlet of the fluid pipeline of the burn-in socket S. In the cooling system, if a high-temperature coolant returns to a water cooling head, it may affect heat exchange efficiency, leading to unstable temperature control. According to the disclosure, the check valve assembly 1160 ensures unidirectional flow of the coolant for discharging of the high-temperature coolant and precluding the return of the high-temperature coolant to the water cooling head, thereby maintaining stabe cooling performance. On the other hand, if a leak occurs within the input closed loop T101 or the output closed loop T102, the vacuum module 1700 will generate a vacuum therein and thereby enter a negative pressure state (for example, to prevent further leakage), and thus switching occurs between the check valve assemblies 1160, allowing the coolant to enter a negative-pressure storage tank for recycling. The check valve assembly 1160 comprises a valve body 1161, a driving block 1162, a check valve 1163, a driving rod 1164, and a solenoid valve 1165, wherein the valve body 1161 is configured to be fluidly connected to the input closed loop T101 and the output closed loop T102. The driving block 1162, check valve 1163, and driving rod 1164 are disposed in the valve body 1161. Owing to the driving rod 1164, the solenoid valve 1165 drives the movement of the driving block 1162. The check valve 1163 has an ejector portion 1166 that matches the oblique surface of the driving block 1162, allowing the check valve 1163 to be operatively positioned in an open state (as shown in FIG. 6A) and a closed state (as shown in FIG. 6B) and thereby movable therebetween. When the high-temperature coolant returns, the check valve 1163 further controllably enters the closed state under the thrust of the returning high-temperature coolant or according to the variation in the temperature sensed by the solenoid valve 1165, thereby stopping the flow of the high-temperature coolant. When the system is operating in a negative-pressure recycling mode, a negative-pressure signal triggers the solenoid valve 1165 such that the solenoid valve is powered to generate magnetic force; as a result, the driving rod 1164 causes the driving block 1162 to move and push the ejector portion 1166 of the check valve 1163 such that the check valve 1163 enters the closed state, allowing the check valve 1163 to close a normal coolant passage, thereby stopping the coolant from flowing toward the water cooling head. Upon the removal of the negative-pressure, the solenoid valve 1165 loses power, and the driving block 1162 releases pressure to allow the driving rod 1164 to return to its initial position, restoring the normal mode. Referring to FIG. 7A and FIG. 7B, in the second embodiment of a check valve assembly of the disclosure, a check valve assembly A1160 comprises a valve body A1161, a check valve A1163, a driving rod A1164, and a solenoid valve A1165. The valve body A1161 is configured to be fluidly connected to the input closed loop T101 and the output closed loop T102. The solenoid valve A1165 controlls the check valve A1163 rotating via the driving rod A1164. In a specific embodiment of the disclosure, in the normal mode, the check valve A1163 automatically opens toward side B of the valve body A1161 to allow the coolant to enter a circulation state when the coolant flow on side A of the valve body A1161 is large. When the coolant flow on side A is less than that on side B, the backflow from side B causes the check valve A1163 switches to a closed state as a result of the backflow from side B. When the system is operating in a negative-pressure recycling mode, a negative-pressure signal triggers the solenoid valve A1165 such that the solenoid valve A1165 controlls the driving rod A1164 rotating; as a result, the check valve A1163 switches to the closed state and thereby closes the normal coolant passage, stopping the coolant from flowing toward the water cooling head. Upon the removal of the negative pressure, the solenoid valve 1165 loses power; the driving block 1162 releases pressure, and the driving rod 1164 returns to its initial position, thereby returning to the normal mode. The disclosure provides check valve assemblies in two aspects, but the disclosure is not limited thereto. According to the disclosure, a check valve is disposed at at least one of the inlet and outlet of the fluid pipeline of each of the burn-in sockets S, but the disclosure is not limited thereto in terms of quantity and position.

Referring to FIGS. 4A-4C and FIG. 5, the liquid-cooling heat dissipation modules 1200 each comprise a water tank 1210, a transport conduit T200, and a plurality of fans 1220. The water tanks 1210 are configured to contain coolant and fluidly connected to the fluid pipelines T100 of the burn-in boards 1100 via the transport conduits T200. The plurality of fans are disposed on the water tank 1210 and arranged in an array to dissipate heat through thermal convection using the coolant in the water tank 1210. More specifically, the fluid pipelines T100 of the burn-in boards 1100 are fluidly connected to the transport conduits T200 of the liquid-cooling heat dissipation modules 1200 through a pair of fluid connectors 1150 to form a closed loop, allowing the coolant within the closed loop to undergo heat exchange in the water tanks 1210 in the liquid-cooling heat dissipation modules 1200. As shown in FIG. 5, the high-temperature coolant within the input closed loops T101 flows into the water tanks 1210 of the liquid-cooling heat dissipation modules 1200 through the fluid connectors 1150 and the transport conduits T200 fluidly connected to the fluid connectors 1150. Then, the high-temperature coolant in the water tanks 1210 transfers heat to heat dissipation fins or heat pipes made of aluminum or copper, and the heat is further removed by the fans 1220 through ventilation. Finally, the high-temperature coolant is cooled down inside the water tanks 1210 and flows toward the output closed loops T102 through the fluid connector 1150 and the transport conduits T200 fluidly connected to the other fluid connector 1150 to allow the burn-in sockets S to undergo heat dissipation. A back board 1300 is electrically connected to and between each of the burn-in boards 1100 and a corresponding one of the liquid-cooling heat dissipation modules 1200, and is configured to receive power mentioned above. In another embodiment of the disclosure, the back boards 1300 can be dispensed with, while the burn-in boards 1100 and the liquid-cooling heat dissipation modules 1200 receive power from the rack power PW directly. In another embodiment of the disclosure, all the liquid-cooling heat dissipation modules 1200 are replaced with a plate heat exchanger, and the plate heat exchanger is effective in enhancing heat dissipation performance without any additional fans and thus precluding noise otherwise generated from fans.

Furthermore, in other specific embodiments of the disclosure, a connection interface I, as shown in FIG. 4D, is disposed between the burn-in board 1100 and the back board 1300 or the liquid-cooling heat dissipation module 1200. The connection interface I has an adapter hole H. The adapter holes H are in fluidic communication with the transport conduits T200 of the liquid-cooling heat dissipation modules 1200. The adapter holes H are configured to be joined to the fluid connectors 1150 with different specifications. In other words, the fluid pipelines T100 with different specifications or designs are joined to the transport conduits T200 via the adapter holes H. On the whole, the connection interfaces I are configured to serve adaption purposes, depending on the designs of the burn-in boards 1100, the liquid-cooling heat dissipation modules 1200 or the back boards 1300; as a result, each of the burn-in boards 1100, a corresponding one of the liquid-cooling heat dissipation modules 1200, and a corresponding one of the back boards 1300 are electrically connected to each other or fluidly connected to each other. Owing to the connection interfaces I, fluid pipeline structures or electrical structures of the burn-in boards 1100, the liquid-cooling heat dissipation modules 1200 or the back boards 1300 need not be designed anew. As shown in FIG. 4A and FIG. 4E, the burn-in boards 1100 each comprise the busbar connector 1140 electrically connected to an electrode plate 1310 of the back board 1300 to allow the burn-in boards 1100 to receive power from the rack and distribute the power to the components on the burn-in boards 1100. In a preferred embodiment of the disclosure, the busbar connector 1140 is configured to be hot-swappable such that an apparatus can be plugged in or unplugged while the system is operating (i.e., without shutting it down). Therefore, the system recognizes and configures a new apparatus or terminates the connection of an old apparatus in real time. It can adapt to instantaneous power fluctuations and thus protect the apparatus against current surges. It allows real-time hardware replacement without affecting normal system operation. The hot-swappable design eliminates the need for additional power line installation, enhancing the flexibility and availability of the system. In a specific embodiment of the disclosure, the busbar connector 1140 functions as an interface for data transmission between hardware components. Specifically, the busbar connector 1140 is communicatively connected to different computer components (for example, CPUs, memory, input/output apparatuses), and thus different computer components transmit commands and data to each other via the busbar connector 1140, enabling data exchange. The busbar connector 1140 is configured to be implemented with, for example, PCIe, USB, SATA, Thunderbolt, and other interfaces. The electrode plate 1310 is configured to function as a corresponding socket. According to the disclosure, the electrode plate 1310 is not limited in terms of shape or structure and is, for example, a corresponding socket, but the disclosure is not limited thereto.

In another embodiment of the disclosure, as illustrated by FIG. 8, the bottoms of the plurality of burn-in sockets S of the burn-in boards 1100 are further fluidly connected to second fluid pipelines T120, whereas the second fluid pipelines T120 are fluidly connected to the transport conduits T200 of the liquid-cooling heat dissipation modules 1200 via one pair of second fluid connectors 1151, Therefore, according to the disclosure, the heat dissipation mechanism is not restricted to the top spaces of the burn-in boards 1100, and heat dissipation components are disposed in the bottom spaces of the burn-in boards 1100, thereby enhancing heat dissipation efficiency.

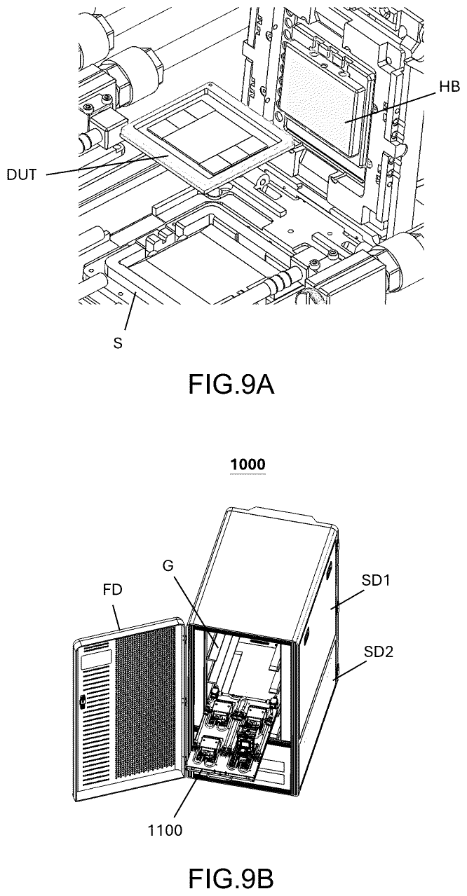

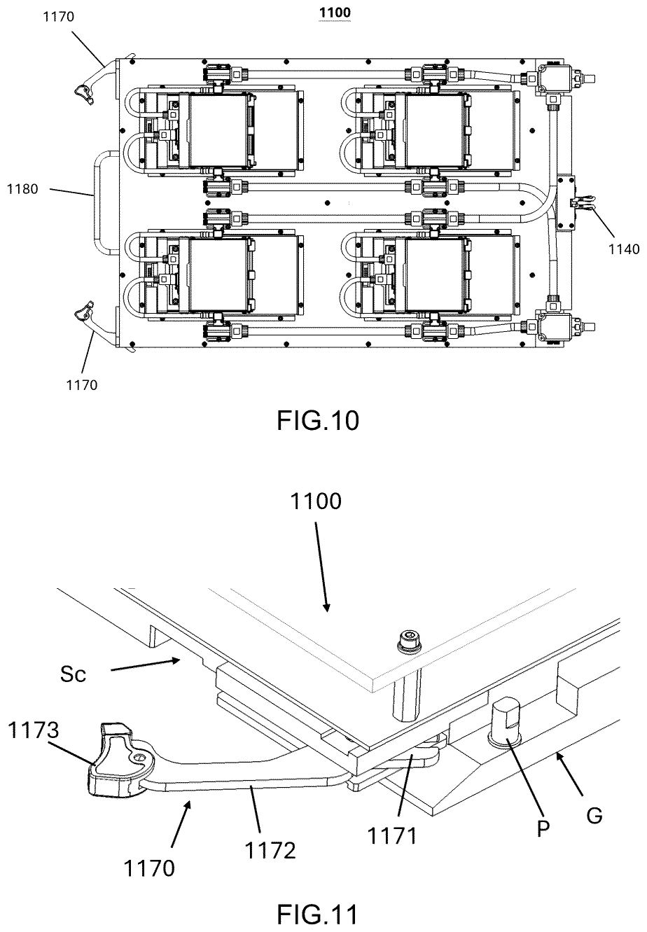

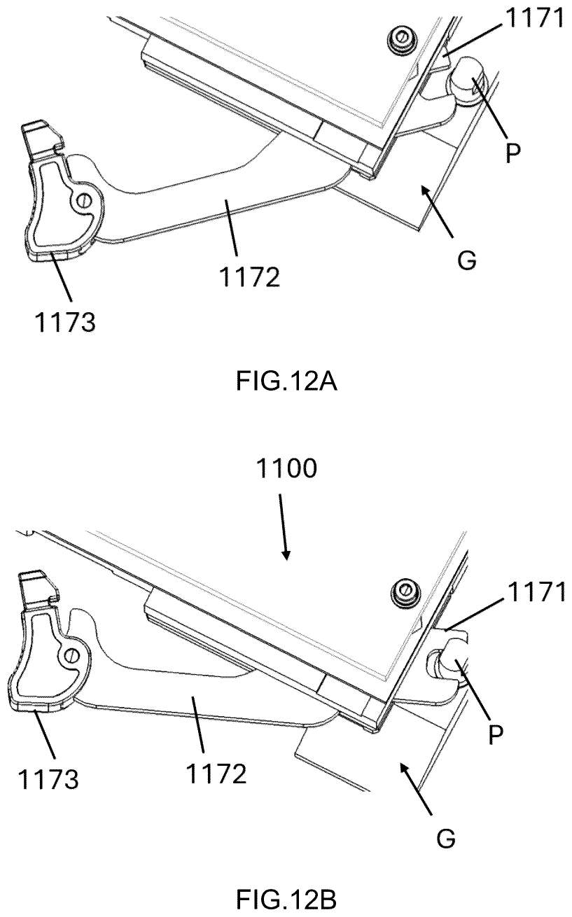

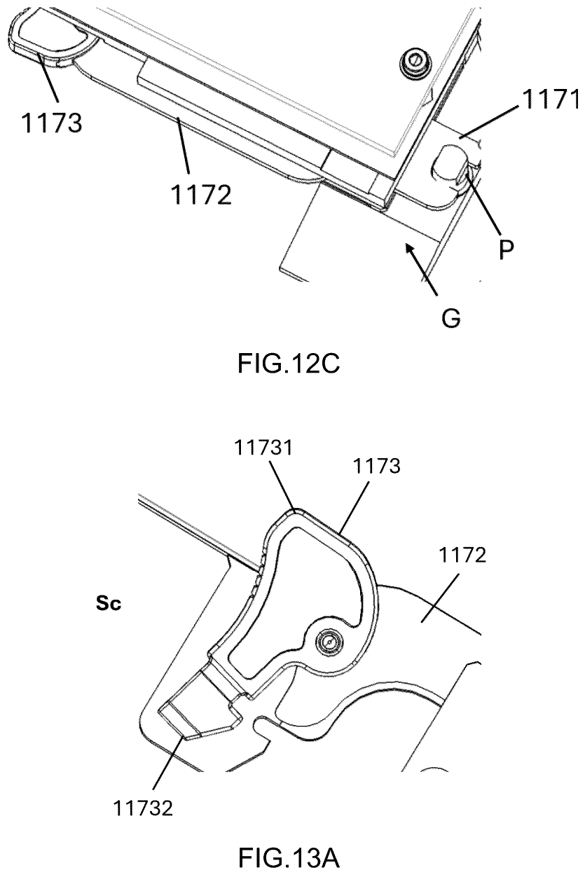

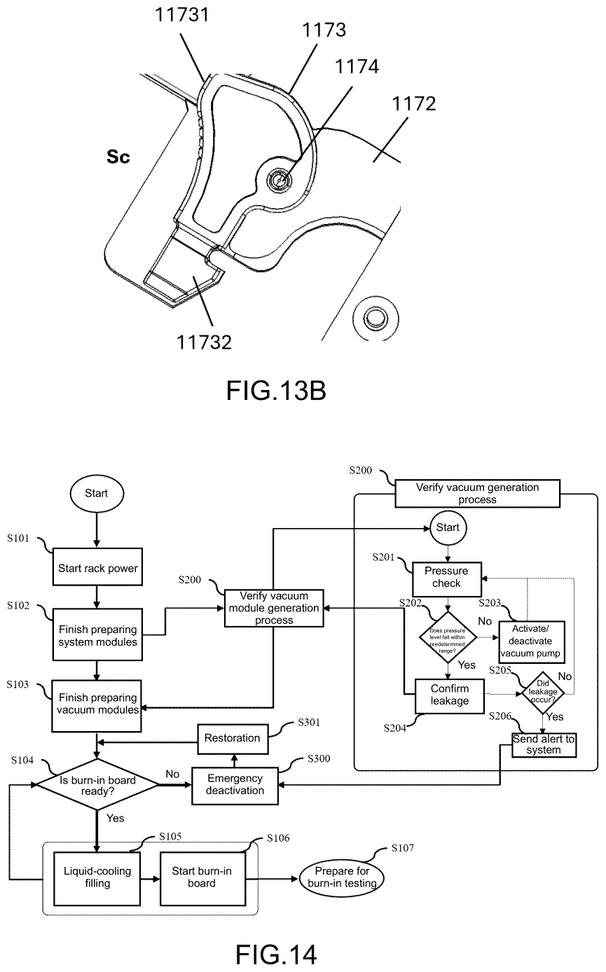

The burn-in boards 1100 are inserted into the rack R and thus positioned in place relative to the liquid-cooling heat dissipation modules 1200. Referring to FIG. 9A and FIG. 9B, devices under test DUT are placed in the burn-in sockets S respectively, and the upper covers of the burn-in sockets are closed S, allowing the heating block HB to come into contact with the devices under test DUT; thus, as mentioned earlier, the burn-in boards 1100 are inserted into the rack R along the guide rails G, and in consequence the burn-in boards 1100 are joined to the liquid-cooling heat dissipation modules 1200, so as to form a closed loop comprising the fluid pipelines T100 of the burn-in boards 1100 and the transport conduits T200 of the liquid-cooling heat dissipation modules 1200, as shown in FIG. 4A through FIG. 4C. The disclosure further provides a positioning mechanism that ensures that the burn-in boards 1100 can be tightly joined to the liquid-cooling heat dissipation modules 1200 without causing an external gas to flow into the closed loop. As shown in FIG. 10 and FIG. 11, the positioning mechanism comprises a positioning mechanism 1170 of the burn-in board 1100 and a pin P on a corresponding one of the guide rails G. The positioning mechanism 1170 can be contained in the burn-in board 1100 and comprises a first portion 1171, a second portion 1173, and an arm portion 1172 connected to the first and second portions 1171 and 1173. The first portion 1171 is a concave portion. Specifically, as shown in FIG. 12A through FIG. 12C, when the burn-in boards 1100 move along the guide rails G, the first portion 1171 enables the pin P to be contained in a concave portion of the first portion 1171; as a result, the first portion 1171 engages with the pin P to cause the arm portion 1172 rotating relative to the pin P, and in consequence the second portion 1173 enters a containment space Sc in the burn-in board 1100, allowing the burn-in board 1100 to be positioned at a location conducive to formation of the closed loop. In an embodiment of the disclosure, as illustrated by FIG. 13A and FIG. 13B, the second portion 1173 further comprises a main body 11731 and an end portion 11732. The main body 11731 rotates relative to the arm portion 1172. When the second portion 1173 enters a containment space Sc in the burn-in board 1100, a groove on the end portion 11732 engages with any other positioning structure or a convex portion disposed in the containment space Sc, allowing the end portion 11732 to be fixed in place; as a result, the positioning mechanism 1170 is entirely prevented from rotating, and thus the burn-in board 1100 can be positioned at a location conducive to formation of the closed loop. An unlocked process entails rotating the main body 11731, a portion of which is exposed from the containment space Sc, to cause the groove on the end portion 11732 to separate from the other positioning structure or the convex portion disposed in the containment space Sc, and pulling the burn-in board 1100 along the guide rails G and out of the rack R using a handle 1180 (shown in FIG. 10) disposed on the burn-in board 1100, thereby allowing the outward-pull of the burn-in board 1100 along the guide rails G and from the rack R to be free of hindrance because of the rotation of the first portion 1171 relative to the pin P.

Referring to FIG. 14, there is shown a flowchart of a liquid-cooling method for use in burn-in testing according to the disclosure. In Step S101, the system starts host power, confirms that the power supply is normal, performs a self-check of the power supply status, and ensures all modules are powered. Step S102 entails checking the modules (for example, the burn-in board management module 1500, vacuum module 1700, and liquid cooling module 1800) to determine whether the modules are functioning properly before proceeding to Step S200. Step S200 entails verifying the completion of a vacuum generation process, followed by sending an error message, initiating an emergency deactivation procedure, or issuing a related notice in the event of an abnormality.

Then, in Step S201, the vacuum module 1700 uses a pressure sensing unit to monitor the pressure level within the closed loop, with the pressure sensing unit disposed in the fluid pipeline T100 or water tank 1210 to sense the pressure level within the closed loop. In Step S202, the vacuum control unit 1530 receives a pressure value fed back by the pressure sensing unit and determines whether the pressure level falls within a predetermined range. If the determination is affirmative, the process flow of the method will proceed to Step S204. If the determination is negative, Step S203 entails automatically controlling the operation of the vacuum pump to increase the pressure within the closed loop and thereby regulate the pressure within the closed loop before proceeding to Step S201 again to perform a pressure check until confirming that the pressure level falls within the predetermined range. In Step S202, the vacuum pump is fluidly connected to the fluid pipelines T100 or the water tanks 1210 throughout the pressure regulation process. In Step S204, regarding the vacuum control unit 1530, a water level sensor is fluidly connected to the fluid pipelines T100 or the water tanks 1210 to perform water level sensing and monitor a leakage level within the closed loop. In Step S205, if the water level sensing process reveals a normal water level, the process flow of the method will proceed to Steps S201~S204. If the water-level sensing process in Step S205 reveals an abnormality, such as a continuously declining water level, the process flow of the method will proceed to Step S206 to send an alert to the system. Then, the process flow of the method proceeds to Step S300 to urgently deactivate the currently operating system. If any one of the aforesaid steps reveals an abnormality, such as a pressure abnormality and a liquid-cooling abnormality, the step will further entail taking measures to perform an emergency shutdown and ensure apparatus security. In Step S301, the coolant is extracted back to the water tanks 1210 through generating in the liquid-cooling heat dissipation modules 1200 a negative pressure under which the coolant is delivered from the closed loop to the water tanks 1210 of the liquid-cooling heat dissipation modules 1200 by the vacuum module using a water pump, or using a gas pump connected to the closed loop, and then operation personnel carry out a repair process at a point of leakage, with the negative pressure indicating that the pressure within the closed loop is lower than the external ambient pressure when the liquid-cooling heat dissipation modules are configured to contain a coolant. Step S301 further entails performing a restoration procedure and attempting to restart the system. If the restoration and restart succeeds, the process flow of the method will return to Step S103 to perform a new check. If the restoration and restart fails, the emergency deactivated state will remain active, allowing time for repair personnel to arrive. In a specific embodiment of the disclosure, Step S200 persists until it confirms that the entire system can perform burn-in testing safely and consistently and provide an abnormality handling mechanism.

Upon completion of the aforesaid confirmation provided in Step S200, the process flow of the method will return to Step S103 and Step S104. Step S104 entails checking the burn-in board 1100 to determine whether it is ready, and entails checking the heat dissipation module, sensor, and power in the burn-in board 1100 to determine whether they are stable. If it is determined that they are ready and stable, the process flow of the method will proceed to Step S105. If the determination is negative, the process flow of the method will proceed to Step S300 and Step S301 to perform the restoration procedure or emergency deactivation procedure. In Step S105, the liquid-cooling control unit 1540 controls the liquid cooling module 1800, and the closed loop is filled with the coolant to ensure proper heat dissipation, ensure normal circulation of the coolant in the closed loop, and preclude overheating. In Step S106, the burn-in board 1100 is started to begin preheating and system preparation, confirm normal operation of components, and keep temperature within a safe range. In Step S107, the system enters burn-in testing preparation stage and awaits user commands or automatically performs testing.

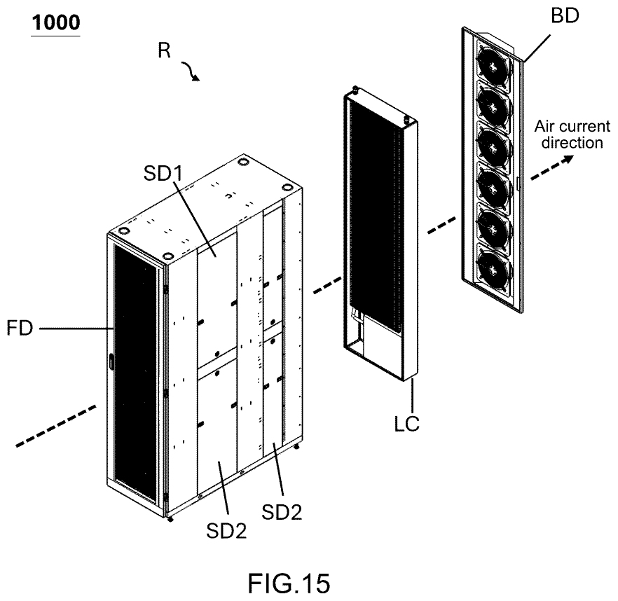

Another embodiment of the disclosure further provides a hybrid burn-in rack that is suitable for use with a back-end semiconductor testing apparatus, features two cooling modes, i.e., liquid-cooling and air-cooling, and automatically switches between the cooling modes to perform heat dissipation according to the power consumption state of the testing apparatus or a cooling system abnormality, so as to ensure a stable and uninterrupted testing process flow and enhance overall system reliability. Specifically, referring to FIG. 15, operating in a way similar to its counterparts in the aforesaid embodiments, the system 1000 in this embodiment is characterized in that the rack R comprises a front door FD, a back door BD, a lateral portion of at least one upper side door SD1, and a lateral portion of at least one lower side door SD2, which collectively define a containment space for containing a plurality of burn-in boards together with the top and bottom of the rack R, thereby allowing burn-in testing to be performed on devices under test. According to the disclosure, a liquid cooling module LC (also known as rear door heat exchanger, RDHx) is disposed between the back door BD and the burn-in boards. The liquid cooling module LC is disposed in the rack R, configured to have substantially the same shape as the back door BD, and connected to the back door BD; thus, waste heat generated during the burn-in testing is subjected to liquid-cooling cooling performed by the liquid cooling module LC and then removed by a heat dissipation device (for example, a fan) disposed on the back door BD. According to the disclosure, the liquid cooling module LC uses a liquid coolant to remove the waste heat generated by electronic components inside the cabinet to lower apparatus temperature, enhance performance, reduce PUE (power usage effectiveness), and save energy. In a specific embodiment of the disclosure, the liquid cooling module LC is also known as cooling liquid advanced rear-door exchanger (CLARX) and configured to be applicable to the rack R powered at 40 Kw or above together with a fan device disposed on the back door BD to enhance heat dissipation efficiency under MEMS control at different temperatures.

In a specific embodiment of the disclosure, the liquid cooling module LC and a heat dissipation device disposed on the back door BD jointly form a hybrid heat dissipation module that features two cooling modes, i.e., liquid-cooling and air-cooling. During the normal operation of the hybrid heat dissipation module, the rack R not only uses a liquid cooling system as a main cooling mechanism but also intelligently switches between the cooling modes in the situations described below.

The first situation is about a switching mechanism in a low-power state. In this situation, when the power consumption during the burn-in testing of the device under test is low (for example, in an idle or low-load test scenario), the system 1000 uses a temperature sensor mounted in place in the rack R to sense the real-time temperature in the rack R and uses a power consumption analysis module (not shown) mounted in place in the rack R to sense the level of power consumption during the burn-in testing performed on the device under test so as to determine that high-efficiency liquid-cooling heat dissipation is currently unnecessary. At this point in time, the system 1000 uses a flow control valve or electronic valve to stop a liquid-cooling fluid from entering the pipeline of the liquid cooling module LC so as to reduce the overall power consumption and cooling burden of the rack R. In another specific embodiment, the system 1000 directly employs air-cooled heat dissipation in the rack R to discharge the internal waste heat of the rack R into the facility air, using a 9+1 hot-swap fan module in a hybrid heat dissipation module as a main heat exchange apparatus. The term “9+1 hot-swap fan module” refers to the configuration and operational architecture of fans provided in a server or high-end rack heat dissipation system and refers to a heat dissipation design featuring redundancy and support for non-disruptive maintenance. The 9+1 hot-swap comprises nine primary fans, one redundant fan, and a hot-swappable architecture. The primary fans typically handle most of the cooling tasks and are distributed on the back door BD or in the critical hot zones in the system 1000. The redundant fan is configured to stay off under normal conditions and only automatically activates when one of the primary fans malfunctions, substituting for the faulty fan to maintain overall heat dissipation efficiency. The hot-swappable architecture means that the fans can be replaced without shutting down or interrupting the system operation. When a fan fails, maintenance personnel can directly pull it out and replace it with a new fan without stopping the operation of the entire rack R. This feature is crucial for uninterrupted semiconductor testing or server application.

The second situation is about a switching mechanism for redundant cooling in a liquid-cooling failure scenario. In this situation, when the cooling system experiences an abnormal condition, such as insufficient coolant water pressure, water quality abnormality, cooling device failure, or water shortage, the rack R instantly triggers the redundant mechanism through its abnormality detection logic, automatically starts the fan system and synchronously adjusts the internal airflow design and thermal control strategy to ensure that the device under test can still complete the testing process normally, even without liquid-cooling support. Even though overall cooling efficiency is slightly low in this mode, the rack R can still effectively prevent the device under test or apparatus from overheating or interrupting the test, thereby providing high fault tolerance.

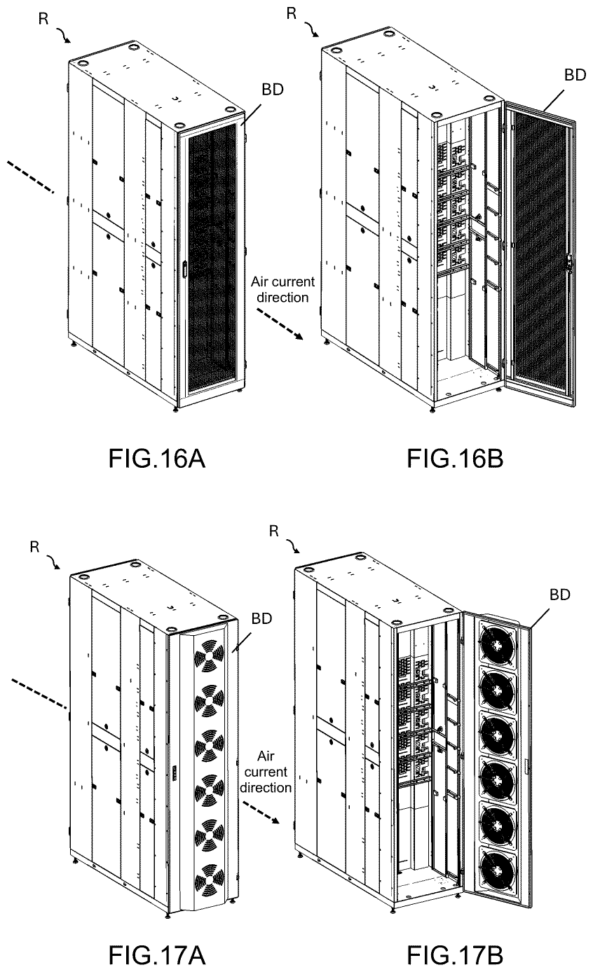

Referring to FIG. 16A and FIG. 16B, in another embodiment of the rack R, a heat dissipation device at the back door BD is selectively configured to release internal heat from the rack R with a mesh door that utilizes a built-in air convection mechanism. As shown in FIG. 17A and FIG. 17B, the heat dissipation device at the back door BD is selectively configured to augment the convection mechanism of the rack R with a plurality of fan devices.

As mentioned earlier, the hybrid heat dissipation module of the disclosure not only introduces RDHx technology into the liquid-cooling framework of the rack R to implement a solution to backward-compatible hybrid cooling but also has a built-in intelligent cooling decision-making module for instantly determining the optimal cooling strategy based on temperature and power consumption conditions, and dynamically switching between a liquid-cooling mode and an air-cooling mode. The system 1000 further offers flexible on-site configuration options, allowing selection of a heat dissipation device for the back door BD based on facility needs to effectively transfers heat from within the rack R to the external environment, achieving overall HVAC load balancing and improved energy efficiency. The hybrid heat dissipation module of the disclosure overcomes the drawbacks of conventional burn-in testing systems using one single cooling mode, either air-cooling mode or liquid-cooling mode, which tends to cause overheating, test interruptions, production efficiency deterioration, and apparatus reliability deterioration in case of system abnormalities, such as coolant supply interruptions, or faulty assessment of the thermal load for the device under test.

On the whole, to fulfill the aforesaid objectives, the disclosure provides a solution to burn-in testing based on water-cooled heat dissipation to precisely control the temperature of a device under test by liquid-cooling technology with a view to overcoming a known drawback of the prior art, i.e., insufficient air-cooled heat dissipation efficiency. Given high-efficiency thermally conductive materials and precise fluid control, a coolant can quickly carry away the heat generated during the operation of the device under test to ensure the stability and uniformity of temperature during the testing process. This technology is effective in enhancing the test reliability of a high-power device under test, lessening the effect of temperature fluctuations on testing results, reducing system power consumption, and enhancing test efficiency and thus applicable to fulfilling the strict environmental testing requirements of high-performance chips. Given the technical features of the rack of the disclosure, the disclosure provides a backward-compatible hybrid cooling system integrating both liquid and air cooling technologies and being based on a temperature/power consumption scenario and dynamic cooling mode switching during fault states.

What is claimed is:

1. A liquid cooling system for use in burn-in testing, comprising:
a rack having a liquid-cooling heat dissipation module; and
a liquid-cooling burn-in board comprising a plurality of burn-in sockets, wherein each of the burn-in socket being fluidly connected to the another burn-in socket via a fluid pipeline;
wherein, when the liquid-cooling burn-in board is inserted into the rack, a fluid pipeline of the liquid-cooling burn-in board is fluidly connected to the liquid-cooling heat dissipation module to form a closed loop, allowing a coolant within the closed loop to undergo heat exchange in the liquid-cooling heat dissipation module.

2. The liquid cooling system of claim 1, wherein the liquid-cooling heat dissipation module has a water tank, a transport conduit, and a plurality of fans, the water tank being configured to contain the coolant and fluidly connected to the fluid pipeline of the liquid-cooling burn-in board via the transport conduit, and the plurality of fans is disposed on the water tank to dissipate heat from the coolant in the water tank.

3. The liquid cooling system of claim 1, wherein the liquid-cooling burn-in board is fluidly connected to a fluid pipeline of the liquid-cooling heat dissipation module via a pair of fluid connectors.

4. The liquid cooling system of claim 1, wherein bottoms of the plurality of burn-in sockets of the liquid-cooling burn-in board are further fluidly connected to a second fluid pipeline, and the second fluid pipeline is fluidly connected to a fluid pipeline of the liquid-cooling heat dissipation module via a pair of second fluid connectors.

5. The liquid cooling system of claim 4, wherein the pair of fluid connectors is a blind mate connector.

6. The liquid cooling system of claim 1, wherein the liquid-cooling heat dissipation module is also configured to further introduce the coolant into the closed loop when the fluid pipeline of the liquid-cooling burn-in board is fluidly connected to the liquid-cooling heat dissipation module.

7. The liquid cooling system of claim 1, further comprising a vacuum module comprising:
a pressure sensing unit for monitoring a pressure level within the closed loop; and
a vacuum pump for regulating a pressure within the closed loop by activating or deactivating based on whether the pressure level falls within a predetermined range.

8. The liquid cooling system of claim 1, further comprising a vacuum module comprising:
a water level sensor for monitoring a leakage level within the closed loop;
a water pump for introducing the coolant from the closed loop to the liquid-cooling heat dissipation module according to the leakage level.

9. The liquid cooling system of claim 1, wherein the rack further comprises a guide rail configured to guide the liquid-cooling burn-in board into connection with the liquid-cooling heat dissipation module;
wherein the guide rail having a pin, and the liquid-cooling burn-in board having a positioning mechanism, when the liquid-cooling burn-in board is connected to the liquid-cooling heat dissipation module, the liquid-cooling burn-in board engages with the pin via the positioning mechanism to allow the liquid-cooling burn-in board to be positioned at a location forming the closed loop.

10. The liquid cooling system of claim 9, wherein the positioning mechanism has a first portion, a second portion, and an arm portion connected to the first portion and the second portion, the first portion being a concave portion;
when the liquid-cooling burn-in board moves along the guide rail, the first portion engages with the pin to drive rotation of the arm portion to cause the second portion to latch into a containment space in the liquid-cooling burn-in board, so as to allow the liquid-cooling burn-in board to be positioned at a location forming the closed loop.

11. The liquid cooling system of claim 9, wherein the liquid-cooling burn-in board receives power from the rack via a busbar connector.

12. The system of claim 1, wherein the liquid-cooling heat dissipation module is a rear door heat exchanger (RDHx).

13. The liquid cooling system of claim 1, wherein a check directional valve is disposed at at least one of an inlet and outlet of a fluid pipeline corresponding in position to each of the burn-in sockets.

14. The liquid cooling system of claim 1, wherein the rack comprises a back door and a liquid cooling module, with the liquid cooling module positioned proximate to the back door to allow the liquid cooling module to absorb heat released by the liquid-cooling heat dissipation module.

15. The liquid cooling system of claim 1, wherein the rack comprises a back door having a plurality of fans.

16. A liquid-cooling method for use in burn-in testing, comprising the steps of:
providing a liquid-cooling burn-in board comprising a plurality of burn-in sockets, wherein each of the burn-in socket being fluidly connected to the another burn-in socket via a fluid pipeline;
providing a liquid-cooling heat dissipation module disposed in a rack and comprising a water tank and a transport conduit; and
fluidly connecting a fluid pipeline of the liquid-cooling burn-in board to the transport conduit of the liquid-cooling heat dissipation module to form a closed loop, so as to allow a coolant in the closed loop to undergo heat dissipation via the liquid-cooling heat dissipation module.

17. The liquid-cooling method of claim 16, further comprising the steps of:
monitoring a pressure level within the closed loop; and
regulating a pressure within the closed loop based on whether the pressure level falls within a predetermined range.

18. The liquid-cooling method of claim 16, further comprising the steps of:
monitoring a leakage level within the closed loop; and
delivering the coolant from the closed loop to the liquid-cooling heat dissipation module according to the leakage level.

19. The liquid-cooling method of claim 18, wherein a negative pressure is generated in the liquid-cooling heat dissipation module using a gas pump connected to the closed loop, so as to extract the coolant from the closed loop to the liquid-cooling heat dissipation module.

20. The liquid-cooling method of claim 19, wherein the negative pressure indicates that pressure within the closed loop is lower than external ambient pressure when the liquid-cooling heat dissipation module is configured to contain the coolant.

21. The liquid-cooling method of claim 16, wherein the coolant is introduced into the closed loop upon confirmation of the state of the burn-in board.
